(19) United States
(12) Patent Application Publication
(10) Pub. No.: US 2015/0022190 A1
(43) Pub. Date: Jan. 22, 2015

(54) Inductive Position Sensor

(71) Applicants: Gordon Brandt Taylor, Berlin, MA (US); Steven E. Beard, Berlin, MA (US)

(72) Inventors: Gordon Brandt Taylor, Berlin, MA (US); Steven E. Beard, Berlin, MA (US)

(21) Appl. No.: 13/946,247

(22) Filed: Jul. 19, 2013

(51) Int. Cl. G01B 7/14; H03B 7/06; G01R 27/26

(52) U.S. Cl. CPC G01B 7/14; G01R 27/2611; H03B 7/06
USPC 324/207.15; 331/167

(57) ABSTRACT

Circuits for inductive position sensor are described.

### CROSS REFERENCE TGO RELATED APPLICATIONS

### Related U.S. Application Data

61/741,487, filed on Jul. 20,2012

### REFERENCES CITED

### US Patent Documents

U.S. Pat. No. 2,452,156 Shover.

U.S. Pat. No. 3,350,660 Engdahl et al.

U.S. Pat. No. 3,397,364 Crandall

U.S. Pat. No. 3,461,400 Koda

U.S. Pat. No. 3,521,158 Murrow et al.

U.S. Pat. No. 3,609,580 Thompson et al.

U.S. Pat. No. 3,619,805 Bean

U.S. Pat. No. 3,701,041 Adler et al.

U.S. Pat. No. 3,732,503 Rapp et al.

U.S. Pat. No. 3,735,244 Gumtau et al.

U.S. Pat. No. 3,756,081 Young

U.S. Pat. No. 3,706,392 Strich

U.S. Pat. No. 3,818,369 Brocker

U.S. Pat. No. 3,848,466 Dial et al.

U.S. Pat. No. 3,872,398 Fausone et al.

U.S. Pat. No. 3,891,918 Ellis

U.S. Pat. No. 3,995,233 Waku

U.S. Pat. No. 4,068,189 Wilson

U.S. Pat. No. 4,182,968 Parker

U.S. Pat. No. 4,284,961 Landau

U.S. Pat. No. 4,310,807 McKee

U.S. Pat. No. 4,618,835 Wilson

U.S. Pat. No. 4,663,542 Buck et al.

U.S. Pat. No. 5,079,502 Grau

U.S. Pat. No. 5,142,226 Sakamoto et al

U.S. Pat. No. 5,767,672 Guichard et al.

U.S. Pat. No. 6,215,365 Kurkovskiy

U.S. Pat. No. 6,335,619 Schwab et al.

U.S. Pat. No. 6,639,759 Inoguchi et al.

U.S. Pat. No. 6,731,119 Haffner et al.

U.S. Pat. No. 7,511,476 Taylor et al.

U.S. Pat. No. 7,528,597 Taylor et al.

### STATEMENT REGARDING FEDERALLY SPONSORED RESEARCH OR DEVELOPMENT

This invention has been created without the sponsorship or funding of any federally sponsored research or development program

### BACKGROUND OF THE INVENTION

This invention relates to electro-mechanical measurement and control systems. These systems measure physical parameters as temperature, pressure, position, velocity, or acceleration and use these measurements to indicate the measured parameter or to control machinery or processes. Historically, the devices used to perform the measurement function have exploited a variable relationship between some electrical phenomenon as capacitance, resistance, inductance and the physical parameter to be measured or, have used the interplay between a magnetic field and an electrical phenomenon.

Position sensors that work by using the variable reluctance of an electromagnetic field about an inductor have been known for many years. With these devices relative motion between an actuator and an inductor (coil) causes a change in the reactance of the coil and that change is used to cause an associated circuit to have a change in electrical output. U.S. Pat. No. 7,511,476 and U.S. Pat. No. 7,528,597 disclose such circuits. In the circuits described in these two patents a tuned oscillator circuit is composed of an inductor and capacitor in series connection with the capacitor connected to ground. The inductor may be the sensing element. It is important for measurement systems that the electrical output created by the system be stable over time at a constant position. There has been a need for more output stability with inductive sensor systems.

Inductors are susceptible to change of inductance as temperature changes. Knowledge of the temperature of the inductor allows compensation for temperature of the inductor for better position measurement accuracy. It is an advantage to have a position sensor transducer with on-board temperature measurement means

A position sensor transducer man be located at some distance from its associated electronic circuitry by a cable. The cable has weight and cost. It is an advantage for a position sensor function and a temperature measurement function to share the same wire pair in a connecting cable

Inductors produce magnetic fields. Inductive sensors rely on change in this magnetic field caused by objects moving in the field to function. It may be that objects move in the field unrelated to the intended sensor function with the result that these objects cause unintended changes to the field which introduces measurement error. Away to shield the magnetic field from unintended error causing influences is desirable.

### BRIEF SUMMARY OF THE INVENTION

In one embodiment, the system of this invention includes a tuned oscillator circuit with variable inductor for measuring a position. The system includes a voltage divider that measures temperature of the inductor.

For a better understanding of the present invention, together with other and further needs thereof, reference is made to the accompanying drawings and detailed description and its scope will be pointed out in the appended claims.

### BRIEF DESCRIPTION OF THE SEVERAL VIEWS OF THE DRAWINGS

The character of the invention, however, may best be understood by reference to one of its structural forms, as illustrated by the accompanying drawings, in which:

FIG. 1 shows the circuit of U.S. Pat. No. 7,528,597

FIG. 2 shows an oscillator circuit for measuring position as of the present invention.

FIG. 3 shows the oscillator circuit of FIG. 2 with temperature measurement function added.

FIG. 4 shows several views of an inductive transducer of the present invention.

### DETAILED DESCRIPTION OF THE INVENTION

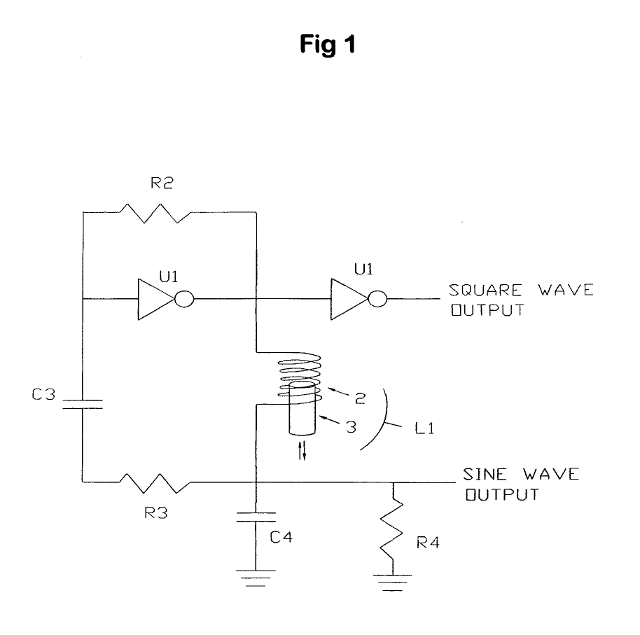

An embodiment of the system of the prior art is shown in FIG. 1. The circuit shown in FIG. 1 is a tuned oscillator circuit. The tuned oscillator circuit is comprised of an amplifier (U1) and two reactive components, an inductor L1 and a capacitor C4. L1 and C4 are in series connection with C4 connected to ground (return) and L1 connected to the output of the amplifier U2. A feedback path is provided from the connection between L1 and C4 to amplifier U2. Frequency of the circuit is taken as output that indicates a position measurement. The frequency of the oscillator is:

$$F = \frac{1}{2 π \sqrt{L 1 * C}} \qquad Formula 1$$

Either one or both of the two reactive components, L1 and C4, can be used as the sensing component. In one embodiment, the inductor L1 is a variable inductor and is the sensing component. The capacitor C provides the capacitance in Formula 1.

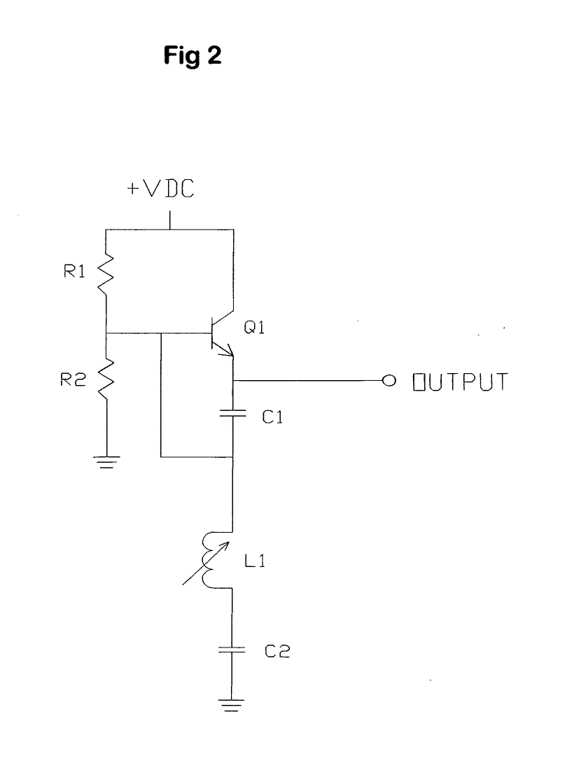

An embodiment of the system of the present invention is shown in FIG. 2. The circuit shown in FIG. 2 is a tuned oscillator circuit. The tuned oscillator circuit is comprised of an amplifier (Q1) and three reactive components, an inductor L1 and two capacitors, C1 and C2. Cl, L1 and C2 are in series connection with C2 connected to ground (return) and C1 connected to the output of the amplifier Q1. The frequency of the oscillator is:

$$F = \frac{1}{2 π \sqrt{L 1 * C}} \qquad Formula 2$$

The inductor L1 is a variable inductor and is the sensing component. The two capacitors in series provide the capacitance in Formula 2. The capacitance of C1 may equal the capacitance of C2. The capacitance of the oscillator tank is divided between C1 and C2 and furthermore the capacitance of C1 is placed between the amplifier Q1I and the inductor L1. The capacitance of C1 buffers the switching of the amplifier Q1 from the inductor L1. This improves circuit stability as compared to the circuit of FIG. 1. Formula 2 and Formula 1 are identical.

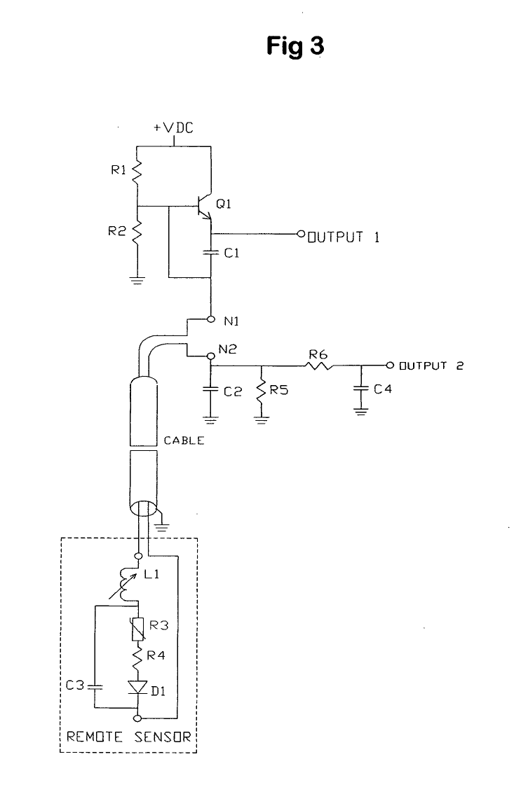

FIG. 3 shows an embodiment of the present invention that has ability to measure position as well as ability to measure temperature of the inductor L1. The circuit shown in FIG. 3 is comprised of modification of the tuned oscillator circuit of FIG. 2 along with a voltage divider circuit for measuring temperature of the inductor. The circuit of FIG. 3 produces a frequency for measuring position The circuit of FIG. 3 also produces a DC voltage that indicates temperature of the inductor L1.

The tuned oscillator circuit (FIG. 3) is comprised of an amplifier (Q1) and four reactive components, an inductor L1 and three capacitors, C1, C2 and C3. C1, L1, C3 and C2 are in series connection with C2 connected to ground (return) and C1 connected to the output of the amplifier Q1. The inductor L1 is a variable inductor. Change of inductance of the inductor causes the frequency of the oscillator to change. The frequency signal at OUTPUT 1 indicates a position measurement.

The voltage divider circuit is a DC connection from +VDC to ground and is comprised of resistor R1 in series connection to node N1 and hence to inductor L1, thermistor R3, resistor R4, diode D1, and resistor R5 to ground. Voltage at node N2 is filtered by a low pass filter and taken as output at OUTPUT 2. The low pass filter is comprised of resistor R6 and capacitor C4. OUTPUT 2 indicates temperature of the position measurement transducer.

Capacitor C3 and Diode D1 divide the current pathways. AC current flows through C3 while DC current flows through D1. In this way the position measurement function and the temperature measurement function are separated through the measurement system.

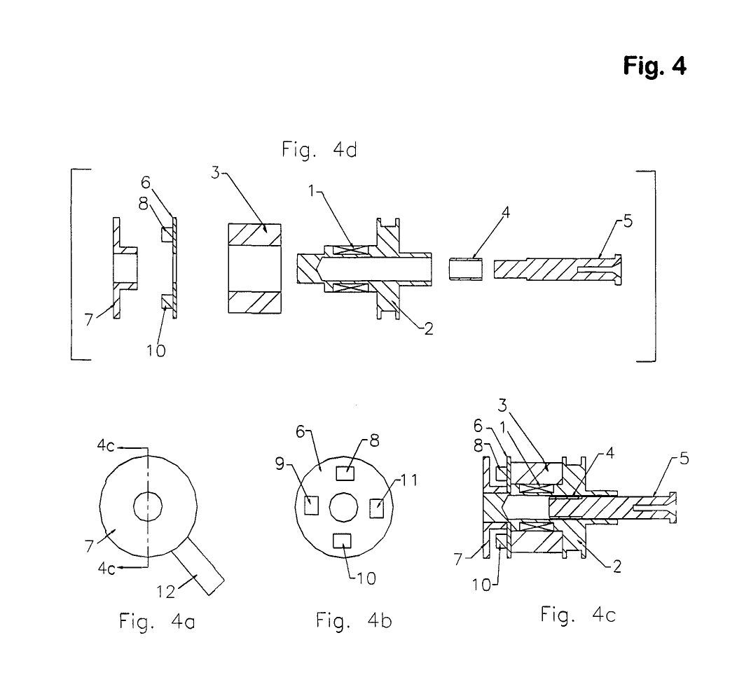

FIG. 4 shows an example of a transducer of the present invention, FIG. 4a is an end view of the transducer. FIG. 4c is a sectional view of the transducer. FIG. 4b is a plan view of PCB 6 with components thermistor 8, resistor 9, diode 10 and capacitor 11. FIG. 4d is an exploded view of the transducer. The transducer contains cylindrical electrical coil 1 on bobbin 2. Ferrite shield 3 is tubular in shape and surrounds the coil. Shield 3 is longer than the coil and overhangs the ends of the coil. For example, the coil may be 1 inch long and the shield may be 1⅛ inches long. In this case, the shield is positioned in relation to the coil so the axial midpoint of the coil and the axial midpoint of the shield coincide. PCB 6 is mounted on the bobbin and mounts components 8, 9, 10, and 11 as shown in schematic FIG. 3. End cap 7 attaches to the bobbin and retains cable 12. Target piece 4 is made of aluminum and is mounted on non metallic probe body 5. The target on probe move in the coil and cause change of reactance of the coil which results in position measurement.

What is claimed is:

1. A sensor circuit comprising:
An oscillator circuit, said oscillator comprising:
a first capacitor, a variable inductor, a second capacitor, and an amplifier;
said first capacitor, said variable inductor, and said second capacitor in series connection, with said first capacitor connected to said amplifier and said second capacitor connected to ground.

2. A sensor circuit of claim 1 further comprising:
a feedback path from the connection between said first capacitor and said amplifier.

3. The sensor circuit of claim 1 wherein output is provided as an oscillatory signal having a frequency.

4. A sensor system comprising a position sensor and a collocated temperature sensor separated by a two conductor cable from the rest of their electronics. Such position sensor further comprising an oscillator circuit having a variable inductor as its sensing element, and such inductor being in series connection with a collocated capacitor. The connection of the inductor not connected to the capacitor being connected to said first conductor of the cable and the connection of the capacitor not connected to the inductor being connected to said second conductor of the cable. Furthermore, such temperature sensor comprised of a thermistor, a resistor, and a diode in series connection. Furthermore, such temperature sensor being part of a voltage divider circuit. Such voltage divider having a thermistor, a resistor, and a diode in series connection with the aforesaid inductor and furthermore, said thermistor, said resistor and said diode being in parallel connection with aforesaid capacitor. Said thermistor being connected to the junction between said inductor and said capacitor and said diode being connected to the junction between said capacitor and said second conductor. Such diode being orientated to provide a DC pathway from power supply +VDC to ground (return).

5. A sensor system of claim 4 further comprising a temperature sensor having a DC pathway from a positive connection of a DC power supply to ground (return); and further comprising a low pass filter to sense a DC potential. Said DC potential being an indication of a temperature measurement.

6. A sensor system of claim 4 wherein output is produced as an oscillatory signal having a frequency. Such frequency being an indication of a position measurement

7. An inductive position sensor transducer wherein a cylindrical electrical coil is surrounded by a ferrite tube; and furthermore said coil has a movable element residing inside the coil. Movement of said element causing a change of reactance of the coil.

8. A sensor circuit of claim 1 further comprising;
An inductive position sensor transducer wherein a cylindrical electrical coil is surrounded by a ferrite tube; and furthermore said coil has movable element residing inside the coil. Movement of said element causing a change of reactance of the coil.
